(19) United States
(12) Patent Application Publication
(10) Pub. No.: US 2003/0216020 A1
(43) Pub. Date: Nov. 20, 2003

(54) Method for forming multi-layer gate structure

(76) Inventors: Neng-Kuo Chen, Hsinchu (TW); Akasaka Yasushi, Isogo-ku (JP)

Correspondence Address: Thomas T. Moga, Esq., Dickinson Wright PLLC, Suite 800, 1901 L Street, N.W., Washington, DC, 20036, US

(21) Appl. No.: 10/337,293

(22) Filed: Jan. 7, 2003

(30) Foreign Application Priority Data
May 17, 2002 (TW) 91110458

(51) Int. Cl. H01L 21/4763; H01L 21/3205; H01L 31/119; H01L 31/113; H01L 29/76; H01L 29/94; H01L 31/062

(52) U.S. Cl. 438/592; 257/412

(57) ABSTRACT

A multi-layer gate structure sequentially formed from a gate oxide layer, a doped silicon layer, a silicon germanium layer, a nitride tungsten layer, and a tungsten layer is described. The polysilicon layer is doped with boron. The silicon germanium layer is formed by deposition or ion implantation process. Because the boron migrates more slowly in the silicon germanium layer, during the thermal process, the boron does not migrate to the nitride tungsten layer and thus the contact resistance of the gate structure is maintained at a desired level.

### FIELD OF THE INVENTION

The present invention relates to a multi-layer gate structure and especially to a multi-layer gate structure with lower contact resistance.

### BACKGROUND OF THE INVENTION

Due to technical progress in semiconductors, the electronic industry has grown rapidly. An important technical improvement is the use of a silicon (Si) or a gallium arsenide (GaAs) semiconductor substrate to form electronic devices thereupon by deposition, lithography, doping, and thermal processes.

Transistors are an important class of electronic devices. The transistors may not only be switches but also be amplifiers in electronic circuits. Hence, to produce high quality transistors on a semiconductor substrate is important for the electronic product.

To satisfy different requirements and development processes, the transistors may be classified as different types, such as bipolar junction transistors, metal-oxide-semiconductor (MOS) transistors, complementary metal-oxide (CMOS) semiconductor transistors and so on.

Of these transistors, MOS and CMOS structures become very important due to the advantage of practical production. Besides, the structure of the MOS and CMOS can combine to form capacitors.

MOS and CMOS devices both have gate structures. FIG. 1 illustrates a typical gate structure. As shown in FIG. 1, a gate 10 includes a gate oxide layer 101, a polysilicon layer 102, and a metal layer 103. For producing the gate 10, after the gate oxide layer 101 is deposited on substrate 11, the polysilicon layer 102 is deposited on the gate oxide layer 101, and then the metal layer 103 is deposited on the polysilicon layer 102.

Due to an adhesion problem between the metal layer 103 and the gate oxide layer 101, the metal layer 103 is not directly deposited on the gate oxide layer 102. Accordingly, a typical process is to form the polysilicon layer 102 on the gate oxide layer 102 to increase adhesion. Furthermore, silicon has not enough conductivity, and therefore the polysilicon layer 102 is doped with P-type ions or N-type ions to enhance conductivity.

An external voltage (not shown) is connected to the metal layer 103 by way of metal leading wires (not shown). The voltage is transmitted to the top of the gate oxide layer 101 by way of the polysilicon layer 102. Gate 10 performs its function with the gate oxide layer 101 made of nonconductive material.

As described above, an important function of the gate 40 is to transmit the voltage. If a resistance of the gate 40 increases, the quality of the gate 40 decreases. Nevertheless, the higher contact resistance becomes a serious problem when the size of the gate decreases due to the increased semiconductor integration.

### SUMMARY OF THE INVENTION

The present invention provides a multi-layer gate structure with a low contact resistance and a manufacturing process thereof.

A multi-layer gate structure according to the present invention sequentially comprises a gate oxide layer, a doped silicon layer, an insulating layer, a glue layer, and a metal layer. The doped silicon layer is doped with P-type ions, such as boron ions. The insulating layer has an insulating component therein, such as germanium. The glue layer comprises a nitride tungsten layer. The metal layer comprises a tungsten layer.

During the thermal process, the P-type ions, such as the boron ions, may diffuse. Because the P-type ions migrate more slowly in the insulating layer, the P-type ions do not migrate to the glue layer and react with the glue layer. The contact resistance of the gate structure is maintained at a desired level. Hence, the small gate structures of high integration semiconductors with low contact resistance can be formed. Therefore, the present invention provides an important contribution to high integration semiconductors.

### BRIEF DESCRIPTION OF THE DRAWINGS

The foregoing aspects and many of the attendant advantages of this invention are more readily appreciated as the same becomes better understood by reference to the following detailed description, when taken in conjunction with the accompanying drawings, wherein:

FIG. 1 is a typical gate structure;

FIGS. 2A through 2E are schematic views showing the manufacturing steps of an embodiment according to the present invention;

FIG. 3 is a manufacture flow chart of the embodiment according to the present invention; and

FIG. 4 is a schematic, cross-sectional view of a preferred embodiment according to the present invention.

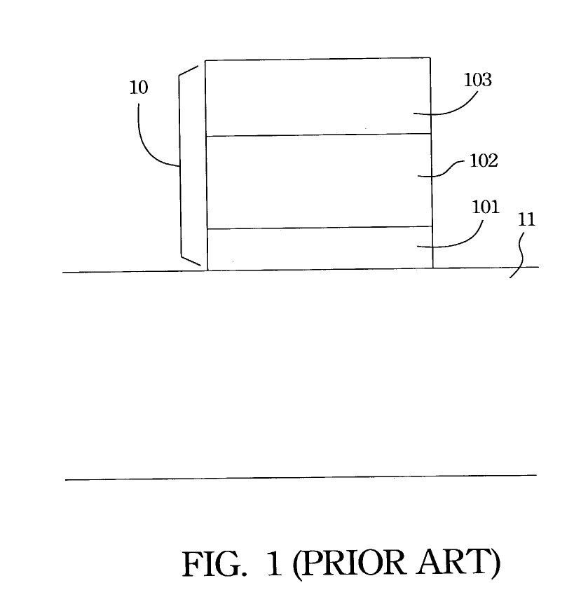

### DETAILED DESCRIPTION OF THE PREFERRED EMBODIMENT

The present invention discloses a method for forming a multi-layer gate structure. The present invention includes a MOS device and a CMOS device but is not limited thereto.

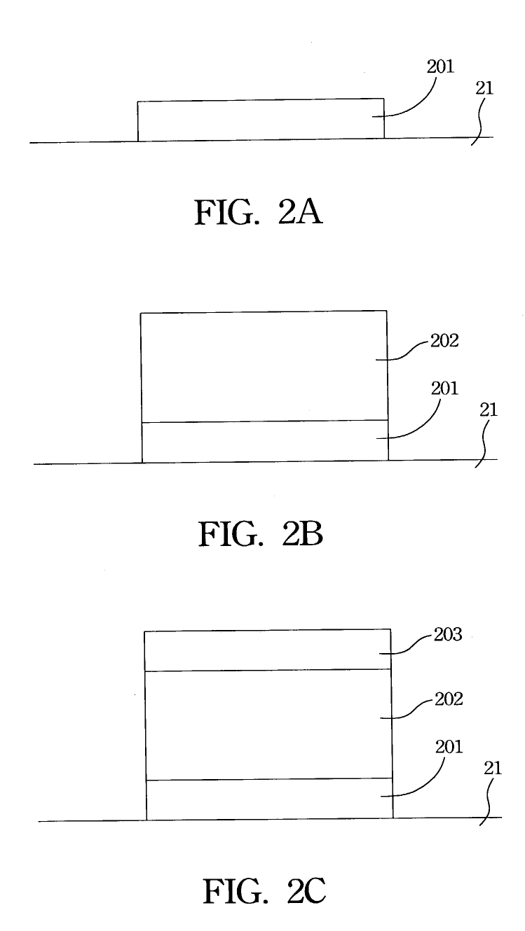

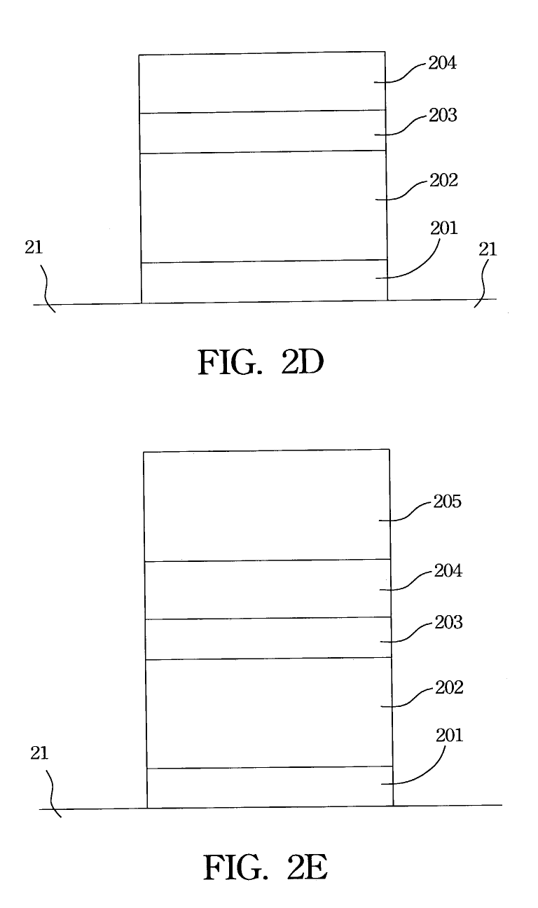

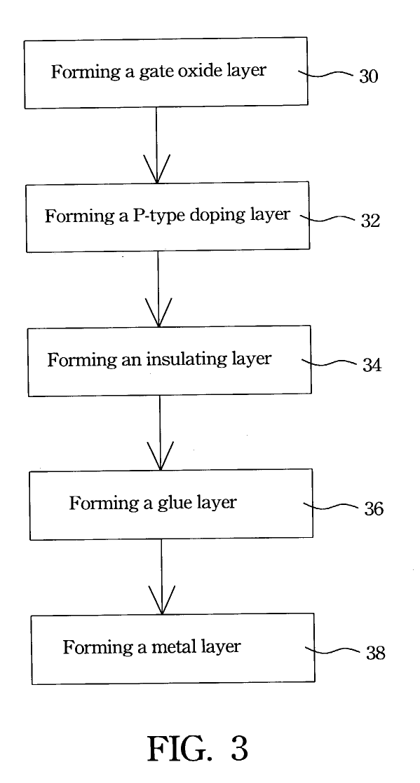

FIGS. 2A through 2E are schematic views showing the manufacturing steps of an embodiment according to the present invention. FIG. 3 is a manufacture flow chart of the embodiment according to the present invention. Referring to FIGS. 2A through 2E and FIG. 3 together, the manufacturing steps of the multi-layer gate structure are described comprehensively.

First, as shown in FIG. 2A, a gate oxide layer 201 is formed on the substrate 21, step 30 of FIG. 3. Then, a doped polysilicon layer 202 is formed on the gate oxide layer 201 as shown in FIG. 2B and step 32 of FIG. 3. An insulating layer 203 is formed on the doped polysilicon layer 202, FIG. 2C and step 34 of FIG. 3. A glue layer 204 is formed on the insulating layer 203, FIG. 2D and step 36 of FIG. 3. Finally, a metal layer 205 is formed on the glue layer 204, FIG. 2E and step 38 of FIG. 3.

The gate oxide layer 201 of the embodiment comprises a silicon dioxide (SiO₂) formed by means of a thermal oven to oxidize the silicon substrate. Further, the doped polysilicon layer 202 is a P-type doped silicon layer in the embodiment. The polysilicon layer is formed with a plurality of silicon grains. The grain boundary has different defects, such as point defects, line defects, surface defects, and bulk defects. The defects can be doped P-type ions, providing acceptors, to increase the conductivity of the doped silicon layer. The P-type ions of the embodiment include boron ions.

Furthermore, the insulating layer 203 is mixed with an insulating component, in which the insulating components in the embodiment include metal materials of germanium, molybdenum, and tantalum. Here, the glue layer 36 increases the adherent force between the metal layer 205 and the insulating layer 202. The glue layer 204 is formed from tantalum nitride and the metal layer 205 is formed from tantalum metal in the embodiment.

In the semiconductor manufacturing process, after forming the gate structure, there are a lot of manufacturing processes to produce the devices, such as a thermal process. During the thermal process, the P-type ion may diffuse to a neighboring layer from the doped silicon layer 202. At this time, the P-type ions may move to the glue layer 204 and then the chemical compound, boron nitride, is formed if there is no insulating layer 203. The boron nitride increases the contact resistance of the gate structure. First, the contact resistance increases caused by the dimensions of the gate structure is smaller. Additionally, the contact resistance is getting higher caused by the P-type ions diffusing to the glue layer. Therefore, the contact resistance may not satisfy the specification requirement and then the circuits may not work normally.

Hence, the present invention provides the insulating layer 203 between the doped silicon layer 202 and the glue layer 204 to solve the contact resistance increase problem. By way of adding the insulating component into the insulating layer, such as germanium, molybdenum and tantalum, the P-type ions, such as boron ions, reduce the diffusion rate in the insulating layer 203 during the thermal process. Therefore, the P-type ions are diffuse only with difficulty into the glue layer 204 and the contact resistance of the gate structure does not increase.

It should be noted that the brief description explains the manufacturing processes of the gate structure without conventional processes, such as the lithography and etching processes. However, the people skilled in the art may reproduce the multiple-layer structure without any experimentation after reading the disclosure of the present invention.

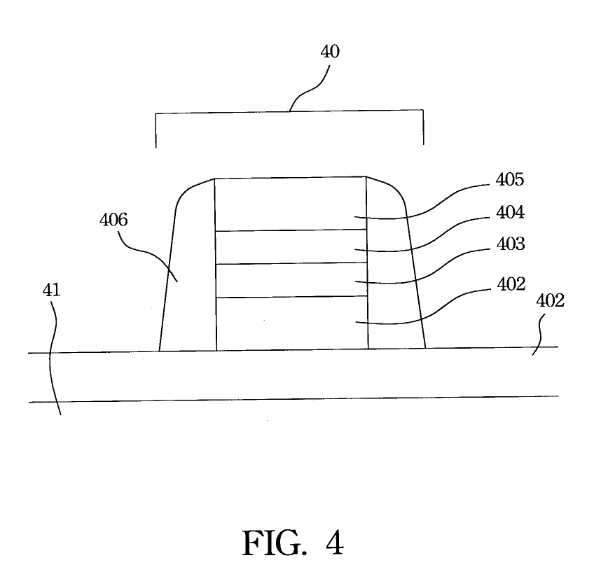

A preferred embodiment is provided to describe the present invention in greater detail. FIG. 4 is a schematic, cross-sectional view of a preferred embodiment according to the present invention. As shown in FIG. 4, a multi-layer gate structure 40 includes a silicon dioxide layer 401, a polysilicon layer 402, a silicon germanium layer 403, a nitride tungsten layer 404, a tungsten layer 405, and spacers 406.

After the silicon dioxide layer 401 formed on a substrate 41, the polysilicon layer 402 is formed on the silicon dioxide layer 401, and then boron is doped into the polysilicon layer 402.

By way of an ion implantation process, the germanium is implanted into the polysilicon layer 402 to form a silicon germanium layer 403. Furthermore, a deposition process may directly deposit the silicon germanium component on the polysilicon layer 402 to form a silicon germanium layer 403, as well.

During a deposition process, the nitride tungsten layer 404 is formed on the silicon germanium layer 403 as a glue layer. Thereafter, a tungsten layer 405 is deposited on the nitride tungsten layer 404 via a sputtering process. Finally, after sequential manufacturing processes, such as a lithography process, an etching process, and so on, spacers 406 are formed and the gate structure 40 is established.

According to experimental data, boron diffuses in the silicon layer about 1E-16 cm² at 800 degree centigrade, while boron diffuses in the silicon germanium layer about 1E-17 cm². Hence, the silicon germanium layer reduces the diffusion rate of the boron and the boron migrates only with difficulty into the nitride tungsten layer. Thus the contact resistance of the gate structure is maintained at a desired level. Accordingly, the quality of the multi-layer gate structure may fulfill the requirement.

The present invention discloses the multi-layer gate structure and manufacturing method thereof to provide a low contact resistance gate structure. Consequently, the small gate structures of high integration semiconductors can be performed. Furthermore, the gate structure is improved and the quality of the semiconductor is improved because the gate structure is an important structure in a semiconductor.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A multi-layer gate structure comprising:
a doped silicon layer doped with P-type ions;
an insulating layer overlying the doped silicon layer, the insulating layer having an insulating component;
a glue layer overlying the insulating layer, wherein the insulating layer prevents the P-type ions from diffusing into the glue layer and thus reduces a contact resistance of the multi-layer gate structure; and
a metal layer overlying the glue layer.

2. The multi-layer gate structure according to claim 1, wherein the multi-layer gate structure further comprises a gate oxide layer and the doped silicon layer overlies the gate oxide layer.

3. The multi-layer gate structure according to claim 1, wherein the P-type ions comprise boron ions.

4. The multi-layer gate structure according to claim 3, wherein the glue layer comprises a nitride tungsten layer.

5. The multi-layer gate structure according to claim 4, wherein the metal layer comprises a tungsten layer.

6. The multi-layer gate structure according to claim 5, wherein the insulating component of the insulating layer comprises germanium.

7. The multi-layer gate structure according to claim 6, wherein the insulating layer comprises a silicon germanium layer formed by a chemical vapor deposition.

8. The multi-layer gate structure according to claim 6, wherein the insulating layer comprises a silicon germanium layer formed by an ion implantation process to implant germanium into the polysilicon layer.

9. The multi-layer gate structure according to claim 5, wherein the insulating component of the insulating layer comprises molybdenum.

10. The multi-layer gate structure according to claim 5, wherein the insulating component of the insulating layer comprises tantalum.

11. A method for forming multi-layer gate structure comprising:
forming a doped silicon layer doped with P-type ions;
forming an insulating layer overlying the doped silicon layer, the insulating layer having an insulating component;
forming a glue layer overlying the insulating layer, wherein the insulating layer prevents the P-type ions from diffusing into the glue layer and a contact resistance of the multi-layer gate structure is reduced; and
forming a metal layer overlying the glue layer.

12. The method for forming a multi-layer gate structure according to claim 11, further comprising forming a gate oxide layer before forming the doped silicon layer, wherein the doped silicon layer overlies the gate oxide layer.

13. The method for forming a multi-layer gate structure according to claim 11, wherein the P-type ions comprise boron ions.

14. The method for forming a multi-layer gate structure according to claim 13, wherein the glue layer comprises a nitride tungsten layer.

15. The method for forming a multi-layer gate structure according to claim 14, wherein the metal layer comprises a tungsten layer.

16. The method for forming a multi-layer gate structure according to claim 15, wherein the insulating component of the insulating layer comprises germanium.

17. The method for forming a multi-layer gate structure according to claim 16, wherein the insulating layer comprises a silicon germanium layer formed bychemical vapor deposition.

18. The method for forming a multi-layer gate structure according to claim 16, wherein the insulating layer comprises a silicon germanium layer formed by an ion implantation process to implant germanium into the polysilicon layer.

19. The method for forming a multi-layer gate structure according to claim 15, wherein the insulating component of the insulating layer comprises molybdenum.

20. The method for forming a multi-layer gate structure according to claim 15 wherein the insulating component of the insulating layer comprises tantalum.
